(19) United States
(12) Patent Application Publication
(10) Pub. No.: US 2024/0363341 A1
(43) Pub. Date: Oct. 31, 2024

(54) GALLIUM NITRIDE GROWTH SUBSTRATE MATERIAL

(71) Applicant: Robert Bosch GmbH, Stuttgart (DE)

(72) Inventors: Mordechai KORNBLUTH, Brighton, MA (US); Bo CHENG, Malden, MA (US); Charles TUFFILE, Swansea, MA (US); Jens BARINGHAUS; Roland PUESCHE, Reutlingen (DE)

(21) Appl. No.: 18/308,064

(22) Filed: Apr. 27, 2023

(51) Int. Cl. H01L 21/02; H01L 29/20; H01L 29/778

(52) U.S. Cl. CPC H01L 21/0242; H01L 21/0254; H01L 29/2003; H01L 29/7786

(57) ABSTRACT

A gallium nitride (GaN) growth layer includes a first surface, a second surface, and a bulk region extending between the first and second surfaces, the bulk region having a polycrystalline material with coefficient of thermal expansion (CTE) of about 2-25 ppm/K above 800 K and one or more spinel compounds having formula (I):(ZnₓCd₁₋ₓ) (Cr_{y}Al_{1-y})₂O₄ (I), where x and y are any number between 0 and 1, one of the first and second surfaces including a GaN epitaxial growth region.

### TECHNICAL FIELD

The present disclosure relates to a gallium nitride (GaN) epitaxial growth substrate and a method of making and using the same.

### BACKGROUND

GaN is an emerging candidate for semiconductors, forecasted to overshadow silicon. GaN has several advantages which make it a very suitable candidate for the power electronics applications: greater electron conductivity, high power density, higher switching frequencies, and higher operational temperatures than silicon. Yet, a hurdle to GaN more widespread use is its production. GaN is typically grown epitaxially as thin films. But suitable substrates for such growth are unavailable and known substrates result in high defect rates.

### SUMMARY

In at least one embodiment, a GaN growth layer is disclosed. The layer may include a first surface, a second surface, and a bulk region extending between the first and second surfaces. The bulk region may have a polycrystalline material with coefficient of thermal expansion (CTE) of about 2-25 ppm/K above 800 K and one or more spinel compounds having formula (I):

(ZnₓCd₁₋ₓ)(Cr_{y}Al_{1-y})₂O₄ (I),

where x and y are any number between 0 and 1.

One of the first and second surfaces may include a GaN epitaxial growth region. The first or second surface may include the polycrystalline material. The polycrystalline material may further include a compound of formula (II):

TiO_{2-δ} (II),

where δ is any number between 0 and 0.5, optionally including a fractional part.

The polycrystalline material may be electrically conductive. The first surface and the bulk region may be encapsulated. The first surface may include the GaN epitaxial growth region. The first surface may be a uniform surface and includes the GaN epitaxial growth region. The polycrystalline material may include Cr₂O₃, ZnCr₂O₄, CdCr₂O₄, or their combinations.

In another embodiment, a GaN semiconductor wafer may include a first layer including a first surface having a GaN epitaxial growth region, a second surface, and a bulk region extending between the first and second surfaces. The bulk region may have a polycrystalline material with coefficient of thermal expansion (CTE) of about 2-25 ppm/K above 800 K and one or more spinel compounds having formula (I):

(ZnₓCd₁₋ₓ)(Cr_{y}Al_{1-y})₂O₄ (I),

where x and y are any number between 0 and 1.

The GaN semiconductor wafer may also include a GaN epilayer adjacent the growth region. The polycrystalline material may further include a compound of formula (II):

TiO_{2-δ} (II),

where δ is any number between 0 and 0.5, optionally including a fractional part.

The compound of formula (II) may include oxygen vacancies. The polycrystalline material may be electrically conductive. The first layer and the bulk region may be encapsulated. The polycrystalline material may include Cr₂O₃, ZnCr₂O₄, CdCr₂O₄, or their combinations. The polycrystalline material may further include carbon.

In yet another embodiment, a GaN semiconductor device is disclosed. The device may include a first layer including a first surface having a GaN epitaxial growth region, a second surface, and a bulk region extending between the first and second surfaces. The bulk region may have an electrically conductive, polycrystalline material with coefficient of thermal expansion (CTE) of about 2-25 ppm/K above 800 K and one or more spinel compounds having formula (I):

(ZnₓCd₁₋ₓ)(Cr_{y}Al_{1-y})₂O₄ (I),

where x and y are any number between 0 and 1.

The device may also include a GaN epilayer adjacent the growth region. The electrically conductive, polycrystalline material may further include an electrically conductive additive. The electrically conductive, polycrystalline material may further include an oxygen vacancy-including compound having formula (II):

TiO_{2-δ} (II),

where δ is any number between 0 and 0.5 including a fractional part.

The GaN epilayer may be immediately adjacent the growth region. The device may be a transistor. The conductive, polycrystalline material may include Cr₂O₃, ZnCr₂O₄, CdCr₂O₄, or their combinations.

### BRIEF DESCRIPTION OF THE DRAWINGS

FIG. 1 is a schematic depiction of a prior art process for GaN growth on a silicon substrate;

FIGS. 2A-2D show schematic non-limiting example depictions of a GaN growth layer disclosed herein according to one or more embodiments disclosed herein;

FIG. 3A shows a non-limiting example of a GaN wafer;

FIG. 3B shows a non-liming example of a GaN semiconductor device;

FIG. 4A shows a scatter plot of bulk modulus for different equations of state (EOS);

FIG. 4B is a correlation matrix for experimental data referenced below;

FIG. 5A shows a plot of estimated coefficient of thermal expansion (CTE), Debye temperature, and cost for identified materials; and

FIG. 5B is a detailed view of a portion of FIG. 5A for relevant materials.

### DETAILED DESCRIPTION

Embodiments of the present disclosure are described herein. It is to be understood, however, that the disclosed embodiments are merely examples and other embodiments may take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present embodiments. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Except in the examples, or where otherwise expressly indicated, all numerical quantities in this description indicating amounts of material or conditions of reaction and/or use are to be understood as modified by the word “about” in describing the broadest scope of the disclosure. Practice within the numerical limits stated is generally preferred. Also, unless expressly stated to the contrary: percent, “parts of,” and ratio values are by weight; the description of a group or class of materials as suitable or preferred for a given purpose in connection with the disclosure implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed.

The first definition of an acronym or other abbreviation applies to all subsequent uses herein of the same abbreviation and applies mutatis mutandis to normal grammatical variations of the initially defined abbreviation. Unless expressly stated to the contrary, measurement of a property is determined by the same technique as previously or later referenced for the same property.

It must also be noted that, as used in the specification and the appended claims, the singular form “a,” “an,” and “the” comprise plural referents unless the context clearly indicates otherwise. For example, reference to a component in the singular is intended to comprise a plurality of components.

As used herein, the term “substantially,” “generally,” or “about” means that the amount or value in question may be the specific value designated or some other value in its neighborhood. Generally, the term “about” denoting a certain value is intended to denote a range within +5% of the value. As one example, the phrase “about 100” denotes a range of 100+5, i.e. the range from 95 to 105. Generally, when the term “about” is used, it can be expected that similar results or effects according to the disclosure can be obtained within a range of +5% of the indicated value. The term “substantially” may modify a value or relative characteristic disclosed or claimed in the present disclosure. In such instances, “substantially” may signify that the value or relative characteristic it modifies is within +0%, 0.1%, 0.5%, 1%, 2%, 3%, 4%, 5% or 10% of the value or relative characteristic.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

In the examples set forth herein, concentrations, temperature, and reaction conditions (e.g., pressure, pH, flow rates, etc.) can be practiced with plus or minus 50 percent of the values indicated rounded to or truncated to two significant figures of the value provided in the examples. In a refinement, concentrations, temperature, and reaction conditions (e.g., pressure, pH, flow rates, etc.) can be practiced with plus or minus 30 percent of the values indicated rounded to or truncated to two significant figures of the value provided in the examples. In another refinement, concentrations, temperature, and reaction conditions (e.g., pressure, pH, flow rates, etc.) can be practiced with plus or minus 10 percent of the values indicated rounded to or truncated to two significant figures of the value provided in the examples.

For all compounds expressed as an empirical chemical formula with a plurality of letters and numeric subscripts (e.g., CH₂O), values of the subscripts can be plus or minus 50 percent of the values indicated rounded to or truncated to two significant figures. For example, if CH₂O is indicated, a compound of formula C_{(0.8-1.2)}H_{(1.6-2.4)}O_{(0.8-1.2)}. In a refinement, values of the subscripts can be plus or minus 30 percent of the values indicated rounded to or truncated to two significant figures. In still another refinement, values of the subscripts can be plus or minus 20 percent of the values indicated rounded to or truncated to two significant figures.

As used herein, the term “and/or” means that either all or only one of the elements of said group may be present. For example, “A and/or B” means “only A, or only B, or both A and B”. In the case of “only A,” the term also covers the possibility that B is absent, i.e. “only A, but not B”.

It is also to be understood that this disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

The term “one or more” means “at least one” and the term “at least one” means “one or more.” The terms “one or more” and “at least one” include “plurality” as a subset.

The description of a group or class of materials as suitable for a given purpose in connection with one or more embodiments implies that mixtures of any two or more of the members of the group or class are suitable. Description of constituents in chemical terms refers to the constituents at the time of addition to any combination specified in the description, and does not necessarily preclude chemical interactions among constituents of the mixture once mixed. First definition of an acronym or other abbreviation applies to all subsequent uses herein of the same abbreviation and applies mutatis mutandis to normal grammatical variations of the initially defined abbreviation. Unless expressly stated to the contrary, measurement of a property is determined by the same technique as previously or later referenced for the same property.

Power electronics are devices that operate on high voltages and currents. Historically, silicon-based metal oxide semiconductors field effect transistors (MOFSETs) dominated conversion of energy to power. While the silicon-based semiconductors continue to improve, the demand for higher power density and efficiency is growing. Additionally, silicon-based devices may have environmentally undesirable emissions associated with their production and manufacturing.

As a result, newly emerging technologies and materials for power electronics have utilized gallium nitride (GaN) whose efficiency, cost, and performance are promising.

GaN is a binary III/V direct bandgap semiconductor. GaN is a very hard material with a Wurtzite crystal structure. It has traditionally been used in light emitting diodes (LED). GaN has a wider band gap in comparison to silicon, specifically 3.4 eV bandgap as opposed to silicon's 1.12 eV bandgap. As a result of the wider bandgap, GaN can withstand higher voltages and higher temperatures. GaN semiconductors are also more efficient than their silicon-based counterparts. Additional advantages of the GaN systems lie in lower cooling requirements, smaller heat sinks, elimination of fans, reduction in size, and overall lower system costs. However, despite all of the advantages, GaN production has been problematic.

Production of any high-quality semiconductor material is complicated. Unlike silicon, which has become “relatively easy” to process into high quality crystals, GaN crystal production of a reasonable quality remains challenging. GaN production challenges include relatively frequent formation of defects including a missing atom or extra atoms, either type of defect potentially resulting in degraded performance and manufacturing errors.

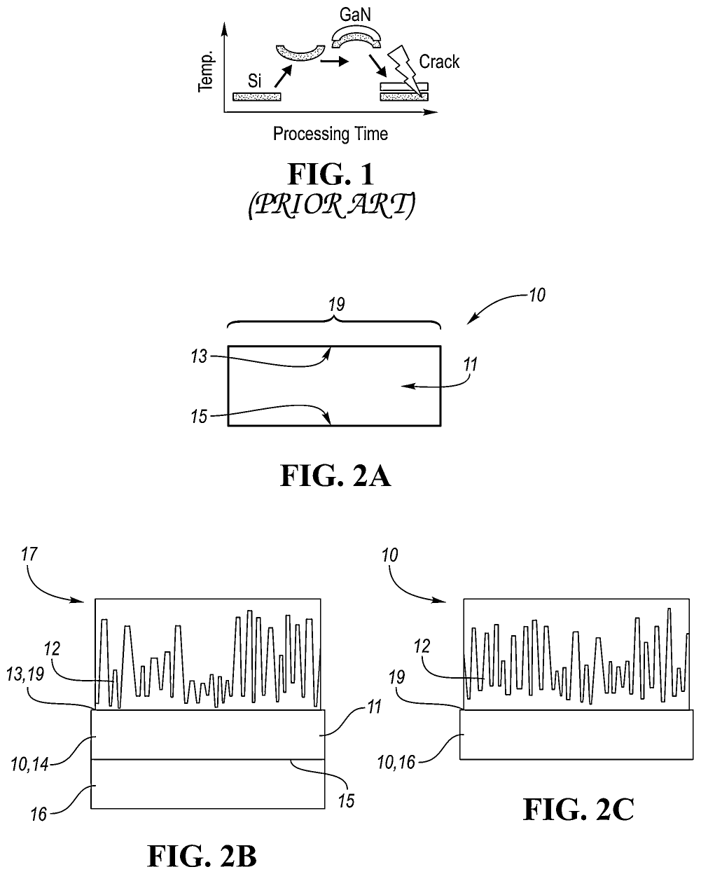

To serve in power electronics, a silicon-wafer manufacturing process has been adopted to produce GaN crystals. The silicon wafers, or silicon carbide (SiC) wafers, serve as a substrate. The role of the substrate is to support growth during the fabrication process. A disadvantage of the typical substrates includes their inflexibility, thickness, and weight which may be much larger than the grown crystal film. Additionally, to remove the substrate from the grown film, several rather costly techniques are typically implemented including laser lift-off and chemical lift-off processes. The methods may be expensive, limited to small wafer size, or forming detects. The typical problems associated with the epitaxial growth of GaN on silicon wafers are mismatched lattice and thermal expansion which may lead to cracking and other defects of the GaN crystals. As the substrate surface such as Si is heated, the substrate attains a curvature, as is schematically shown in FIG. 1. The curvature affects the deposition and may result in cracking of the GaN film as the thermal profile changes during processing. Other substrate materials have been tested such as graphene, graphite, or c-sapphire, each introducing a relatively large number of defects in the GaN epilayers.

Thus, buffer materials have been introduced to form an interlayer in an attempt to minimize the number of defects. Typically, a thin layer of GaN is grown on the aluminum nitride (AlN) layer of a standard silicon wafer using metal organic chemical vapor deposition. The AlN layer may function as a buffer between the wafer and GaN. AlN/AlₓGa₁₋ₓN layers or alternatively AlN/GaN strained superlattices are grown between GaN and Si. An alternative material may be boron nitride (BN), forming a buffer layer between the substrate and the grown GaN, which is cleavable. Yet, defects are still relatively common with the herein-mentioned interlayers and limit the maximum achievable GaN layer thickness, and in turn, the breakdown capability of the electronic devices.

Recently, a polycrystalline aluminum nitride (poly-AlN) based material with a coefficient of thermal expansion (CTE) similar to the a-direction of an epitaxially grown GaN material, around 6 ppm/K above 800 K, has been identified. The associated curvature of Si is therefore compensated by the poly-AlN core. For the capability of growing epitaxial GaN layers on these cores, other layers may be bonded onto this core.

Yet, it is desirable to identify additional materials suitable as an interlayer material or a substrate for epitaxial growth of GaN. The material should be low cost and eliminate lattice mismatch and crystal dislocations.

In one or more embodiments, a material is disclosed. The material disclosed herein solves one or more problems described herein and/or provides the benefits identified herein. The material disclosed herein may minimize curvature, ensure less strain, eliminate lattice mismatch, and/or crystal dislocations, resulting in GaN grown layers with minimal defects. The grown GaN may have hexagonal (wurzite) structure, crystals, microcrystals, n⁻—GaN, n⁺—GaN, p⁺—GaN, the like, or a combination thereof.

The material may form an interlayer or buffer layer between a substrate and GaN. The interlayer may be an epitaxial GaN growth layer, epilayers, or thin film. The substrate may be silicon, SiO₂, SiC, sapphire, c-sapphire, graphene, graphite, diamond, or the like. In one or more embodiments, the material disclosed herein may form the substrate and the interlayer, the chemical composition of each being different. Alternatively, the material disclosed herein may form a substrate for epitaxial GaN growth.

A GaN growth layer may thus include a first surface, a second surface, and a bulk region extending between the first and second surfaces. The first surface, the second surface, the bulk region, or a combination thereof may include the material disclosed herein. Only one or the first and second surfaces may include the material disclosed herein. One of the first and second surfaces may include a GaN growth region.

The GaN growth region may extend the entire surface and/or area of the surface. The surface may also include a non-GaN growth region. The GaN growth region may be arranged in a pattern, be arranged regularly, irregularly, as lines, strips, islands, in a gradient, the like, or a combination.

The first or second surfaces may include an encapsulation to prevent metal fragment contamination of the manufacturing facility. The encapsulation may include a layer of silicon or another material. The encapsulation may form a layer having a thickness lesser than a thickness of the bulk region. The encapsulation layer may enclose the entire bulk region, first surface, second surface, or their combination or be included only on a portion of the first or second surface.

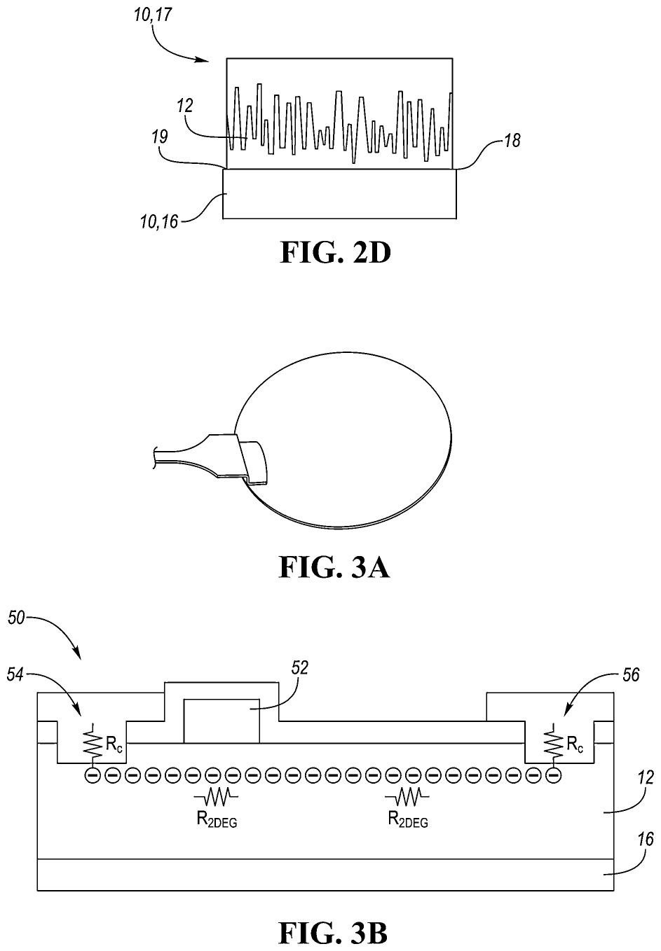

FIG. 2A shows a schematic non-limiting example of a GaN growth layer 10. The GaN growth layer 10 includes the bulk region 11, the first surface 13, and the second surface 15. The first surface includes a GaN epitaxial growth region 19.

Another non-limiting example of a GaN growth layer 10 is shown in FIG. 2B. In FIG. 2B, an interface 17 of the GaN epilayers 12, the GaN growth layer 10 disclosed herein as a buffer or intermediate layer 14, and a substrate 16 is shown. The GaN growth layer includes the bulk region 11, the first surface 13, and the second surface 15. The first surface 13 includes a GaN epitaxial growth region 19.

FIG. 2C shows a schematic non-limiting example of a GaN growth layer 10, where the GaN growth layer 10 forms a substrate 16. The GaN growth region 19 is shown.

FIG. 2D shows another non-limiting example of a GaN growth layer 10. The GaN growth layer 10 is arranged as a substrate 16. The interface 17 includes the GaN epilayers 12, the substrate 16, and an encapsulation layer 18.

The material may be provided as a solid, layer, wafer, solid particles, solid powder, or the like. The layer may be uniform, removable from GaN, having at least one surface the GaN epilayers can be grown on, the GaN growth region. The GaN growth region may be flat, free or substantially free of curvature, concavity, deformations, imperfections, defects.

The material may have a coefficient of thermal expansion (CTE) similar to the GaN CTE. The material CTE may be about 3-9 ppm, 4-8 ppm, or 5-6 ppm/K above 800 K. The CTE may be up to 10, 13, 15, 18, 20, 23, or 25 ppm/K above 800 K. The material CTE may be about, at least about, or at most about 2, 3, 4, 5, 6, 7, 8, 9, 10, 11, 12, 13, 14, 15, 16, 17, 18, 19, 20, 21, 22, 23, 24, or 25 ppm/K above 800 K.

The material may be electrically conductive. The material may include oxygen vacancies, electrically conductive additive(s), or both to render the material electrically conductive. The material disclosed herein may have good electrical conductivity. The material may have an electrical conductivity of about 1-100, 1.5-50, or 2-10 S/m or 100-10000, 150-5000, or 200-1000 S/cm at room temperature in ambient environments. The disclosed material may have an electrical conductivity of about, at least about, more then about, or up to about 0.5, 1.0, 1.5, 2.0, 2.5, 3.0, 3.5, 4.0, 4.5, 5.0, 5.5, 6.0, 6.5, 7.0, 7.5, 8.0, 8.5, 9.0, 9.5, 10, 10.5, 11, 11.5, 12, 12.5, 13, 13.5, 14, 14.5, 15, 15.5, 16, 16.5, 17, 17.5, 18, 18.5, 19, 19.5, 20, 25, 30, 35, 40, 45, 50, 55, 60, 65, 70, 75, 80, 85, 90, 95, 100 S/m, or any range in between, at room temperature in ambient environments.

The material may be polycrystalline. The material may include a spinel. The material may be a combination of a spinel compound and titania. The disclosed material may include, comprise, consist essentially of, or consist of one or more compounds of formula (I):

(ZnₓCd₁₋ₓ)(Cr_{y}Al_{1-y})₂O₄ (I),

where x and y are any number between 0 and 1.

In formula (I), x may be 0, 0.1, 0.2, 0.3, 0.4, 0.5, 0.6, 0.7, 0.8, 0.9, or 1.

In formula (I), y may be 0, 0.1, 0.2, 0.3, 0.4, 0.5, 0.6, 0.7, 0.8, 0.9, or 1.

Non-limiting example compounds of formula (I) may be Cr₂O₃, ZnCr₂O₄, CdCr₂O₄, or their combinations. Additional spinel compounds are identified in the experimental section below.

The disclosed material may further include one or more compounds of formula (II):

TiO_{2-δ} (II).

where δ is any number between 0 and 0.5.

In formula (II), δ may be any number between 0 and 0.5. 8 may optionally include a fractional part such as decimals and/or hundredths and denotes oxygen vacancies. δ may be 0.1, 0.2, 0.3, 0.4, or 0.5. 8 may be any number between 0 and 2 including tenths, hundredths, or both. δ may be 0.01, 0.02, 0.03, 0.04, 0.05, 0.06, 0.07, 0.08, 0.09, 0.1, 0.11, 0.12, 0.13, 0.14, 0.15, 0.16, 0.17, 0.18, 0.19, 0.20, 0.21, 0.22, 0.23, 0.24, 0.25, 0.26, 0.27, 0.28, 0.29, 0.30, 0.31, 0.32, 0.33, 0.34, 0.35, 0.36, 0.37, 0.38, 0.39, 0.40, 0.41, 0.42, 0.43, 0.44, 0.45, 0.46, 0.47, 0.48, 0.49, or 0.50.

δ may include a range including any number named above while excluding at least one number mentioned above. For example, δ may equal 0.1 to 0.5 with the exclusion of 0.4.

In one or more embodiments, the oxygen vacancies within the material contribute to beneficial properties of the material. Thus, the oxygen vacancies are formed and preserved on purpose, and processes which would eliminate presence of oxygen vacancies may be avoided or excluded during the material synthesis and/or use.

Oxygen vacancies in the material may be characterized as a quantitatively smaller amount of oxygen atoms present in the material than expected in the parent material's crystal lattice. Oxygen vacancies are typically formed by removing an oxygen from a compound of oxygen, for example by annealing in a reducing atmosphere of N₂. Ar, or the like. In another embodiment, annealing may be carried out in a vacuum furnace. The oxygen vacancies may render the material non-stoichiometric or deviating from stoichiometry such that the elemental composition of the material may not be represented by a ratio of well-defined natural numbers. The material; however, may be stoichiometric.

In some applications, oxygen vacancies may be perceived as undesirable defects influencing structural, electrical, optical, dissociative and reductive properties, or other properties in a manner which is not suitable for various applications. In contrast, the materials disclosed herein have desirable properties due to oxygen vacancies being present. While a base or parent compound and a material with oxygen vacancies may have common morphology, structure, or lattice to a certain degree, their properties may significantly differ. Such is the case with the disclosed material having oxygen-deficient stoichiometry. The material may have crystalline structure alike the parental TiO₂ phase. But even the crystalline structure differs due to the oxygen deficiencies. For example, the disclosed material's lattice may include extra bonds or lack bonds in spaces where the parental phase includes a bond.

Without limiting the disclosure to a single theory, it is believed that due to presence of the oxygen vacancies, the disclosed material has different properties than the parental phase, for example electrical conductivity as the oxygen vacancy allows for electrical conduction in the material. An additional difference may be observed in its physical appearance. The presence of oxygen vacancy in the bulk TiO₂ structure changes the electrical conductivity of the material. The disclosed material including an oxygen vacancy may be thus electrically conductive.

In one or more embodiments, the method of preparing the herein-disclosed material is disclosed. The method may include preparing a material of formula (I), formula (II), or a combination thereof. The method may include preparing the material of formula (I), formula (II), or both by tape casting. The method may include preparing a slurry in which particle size is about 700-1500, 600-1200, or 500-1000 nm. The slurry may be tape cast to a solid substrate, such as a substrate named above. Binder(s) and/or additive(s) may be added to the slurry to achieve a desired viscosity, flexibility, strength, or a combination thereof. The method may include polishing the tape after processing.

The method may include preparing the material of formula (II) separately from material of formula (I). The synthesis of the material of formula (II) may include preparing dry powders of TiO and/or Ti₂O₃. The method may include forming a mixture of the TiO and Ti₂O₃. The method may include drying the one or more compounds to be included in the mixture. Drying may be conducted in vacuum or ultra-high vacuum, N₂, Ar, or Ar/H₂ environment. Ultra-high vacuum refers to a regime of pressures lower than about 10-7 pascal or 100 nanopascals (10-9 mbar, ˜10-9 torr).

The dry powder(s) may be compressed into any shape or configuration, for example in a mold. The compressed mixture may be heated by sintering for an amount of time. Sintering is a process of compacting and forming a solid mass of a material by heat and/or pressure without melting it to the point of liquefication or the material's melting point.

The amount of time may be an amount needed for the powder particles to fuse together and create a solid piece, and/or for the compressed material to change appearance. The sintering may be carried out at a temperature which is below the powder mixture's melting point. The temperature may range from about 400 to 2000° C., 800 to 1800° C., or 1200 to 1500° C. in vacuum, N₂, Ar, or Ar/H₂ environment.

The method may include rendering the material disclosed herein conductive. The conductivity may be provided by adding a conductive additive into the slurry to increase conductivity of the material. An example conductive additive may be carbon. Alternatively or additionally, the conductivity of the material may be brought on by introduction of oxygen vacancies.

The method may include providing oxygen vacancies in the material of the formula (I), formula (II), or both. The amount of oxygen vacancies may be tailored depending on the needs of a specific application. The amount of oxygen vacancies in the material of formula (I) may be introduced, controlled, or altered by using carbonate precursors to create a reducing environment. The amount of oxygen vacancies in the material of formula (II) may be introduced, controlled, or altered by controlling, adjusting, or controlling the sintering temperature in the material of formula (II)). The amount of oxygen vacancies may be controlled by the TiO/Ti₂O₃ ratio in the powder mixture. The TiO/Ti₂O₃ ratio may be about 0:100, 1:99, 10:90, 20:80, 30:70, 40:80: 50:50, 60:40, 70:30, 80:20, 90:10, 99:1, or 100:0.

It was surprisingly discovered that in contrast to sintering, annealing destroys oxygen vacancies in the disclosed material. Since the oxygen vacancies are desirable in the disclosed material, annealing, as a process of minimizing crystal defects through a heat treatment and involving heating a material above its recrystallization temperature, maintaining a suitable temperature for a certain amount of time, and then cooling in air, should be avoided.

The method may include using the material disclosed herein. The method may include forming the material as a layer, either a substrate layer or intermediate layer. The layer may have a width, length, and thickness. The layer may be a wafer or a thin slice of the material. The layer may have a circular shape or another shape and/or configuration. The method may further include depositing GaN film on the material for GaN growth and growing epitaxial GaN films on the material. The method may thus include forming a GaN wafer. A non-limiting example of a GaN wafer is shown in FIG. 3A.

The method may include separating or removing the GaN from the material after growth to a predetermined level. Removal may be via cleaving, via use of a tape, or the like. But unlike traditional GaN growth substrates which are removed from the GaN once the GaN growth stops, the material disclosed herein may remain attached to the GaN epilayers and be part of the GaN electronic chip, device, or system. The method may include keeping the GaN film on the material and utilizing the material due to its conductive nature, for example as backside contacts. The material disclosed herein is thus not only a GaN growth material, but also GaN support substrate throughout the GaN wafer, chip, device, system.

The method may further include forming the material with the GaN grown on it into a semiconductor chip, device, or system. The material may be used for production of electronic, electrical products/systems such as semiconductors, LEDs, lasers, radio frequency (RF) devices, transistors, or the like. A non-limiting schematic example of a GaN device 50 utilizing the material disclosed herein to grow GaN epilayers is shown in FIG. 3B. As can be seen in FIG. 3B, a transistor 50 includes a substrate including the material disclosed herein 16, epilayer of GaN 12, a gate 52, a source 54, and a drain 56.

### EXPERIMENTAL SECTION

To identify suitable interlayer or substrate materials, the following properties were identified:
(a) coefficient of thermal expansion (CTE) in the vicinity of 6 ppm/K above 800K (to match a-GaN), which is similar to poly-AlN;
(b) conductivity to enable wafer processing and backside contacts without having to remove the substrate;
(c) cost on-par or less than AlN;
(d) possibility to bond an epi-ready layer on top of the GaN core; and
(e) complementary metal-oxide semiconductor (CMOS) fabrication compatibility.

With respect to (a), CTE is very difficult to compute, and not all materials have available data in the literature, especially for the desired temperature of >800 K (>500° C.). Hence, several approximations to estimate the CTE from available data as described below were used. The symbols used in the equations below are listed in Table 1.

It was observed that above a certain temperature, the CTE approximately flattens as a function of temperature. The temperature is loosely approximated as the Debye temperature, (Θ_{D}), which is the temperature at which the phonons behave semiclassicany. This is

$${Θ}_{D} ≡ \frac{ℏ}{{k}_{B}} \sqrt{\frac{K}{ρ}} {( \frac{6 {π}^{2} ρ {N}_{A} A}{M} )}^{1 / 3} ( assuming {v}_{s} = \sqrt{K / ρ} ) .$$

The heat capacity approaches cᵥ=3R per mol for temperatures T»Θ_{D}; this is known as the Dulong-Petit limit.

The Grüneisen parameter (γ) is a description of how expanding volume lowers the vibrational frequency. In the Quasiharmonic Debye model:

$${γ}_{D} \approx - \frac{\partial ln {Θ}_{D} ( V )}{\partial ln V} .$$

Depending on the theory, we can typically use

$$γ \approx \frac{1}{2} \frac{dK}{dp} - β ,$$

where β is between 0.16 (Slater) and 0.95 (modified free volume), depending on the theory. Two extrema (0.16 and 0.95) were taken as the approximate boundaries for the search.

$$\frac{dK}{dp} = {K}_{0}^{′}$$

may be extracted from an equation of state; typically it is between 3.5 and 4.5 for solids, giving γ between 0.8 and 2.1.

The Grüneisen parameter and thermal expansion relate as

$$γ = \frac{3 {α}_{L} K}{{c}_{p} ρ} = \frac{3 {α}_{L} {v}_{s}^{2}}{{c}_{p}} .$$

If the chemical formula, density, bulk modulus K₀, and anharmonic bulk modulus parameter K₀′ is known, the linear CTE α_{L} for high temperatures T»Θ_{D} can be estimated.

$${α}_{L} = \frac{{k}_{B} {N}_{A} A ρ γ}{K M} \approx \frac{{k}_{B} {N}_{A} A ρ ( {K}_{0}^{′} / 2 - β )}{{K}_{0} M}$$

TABLE 1
Symbols in the equations mentioned above

| Symbol | Value |
|---|---|
| A | Number of atoms per formula unit |
| cₚ | Heat capacity at fixed pressure |
| c_{V} | Heat capacity at fixed volume |
| E | Energy |
| H | Planck's constant |
| K | Bulk modulus (adiabatic) |
| K′ | Anharmonic bulk modulus parameter (dimensionless) |
| kB | Boltzmann constant |
| M | Molar mass [g/mol] |
| N | Number density [num atoms/mol] |
| N_{A} | Avogadro's number |
| p | Pressure |
| R | Gas constant |
| T | Temperature |
| V | Volume |
| v_{S} | Speed of sound |
| α_{L} | Linear coefficient of thermal expansion |
| β | Dimensionless Grüneisen approximation parameter |
| γ | Grüneisen parameter |
| θ_{D} | Debye temperature |
| ρ | Density [mass/volume] |

Density functional theory (DFT) was used to calculate total energy. The DFT solves a system of electronic interactions for the ground-state energy of a material. The publicly available Materials Project database was screened for the following key parameters: chemical formula, V₀ (or density), bulk modulus K, and anharmonic bulk modulus parameter K₀′. The following screening criteria were selected: (a) elemental cost, not including processing, (b) Debye temperature, as estimated with the formula

$${Θ}_{D} = \frac{ℏ}{{k}_{B}} \sqrt{\frac{K}{ρ}} {( \frac{6 {π}^{2} ρ {N}_{A} A}{M} )}^{1 / 3} , ( c ) CTE ,$$

estimated between the limits of β=0.16 and β=0.95, using the approximation

$${α}_{L} = \frac{{k}_{B} {N}_{A} A ρ γ}{K M} \approx \frac{{k}_{B} {N}_{A} A ρ ( {K}_{0}^{′} / 2 - β )}{{K}_{0} M} .$$

The search was chosen to include all materials in the Materials Project which have a known computed equation of state (EOS), with no more than three elements, and a hull energy (defined above) no more than 100 meV/atom. AlN was chosen as a reference material. The search was thus focused on stable elemental, binary, and ternary compositions. The search identified 218 materials meeting the criteria.

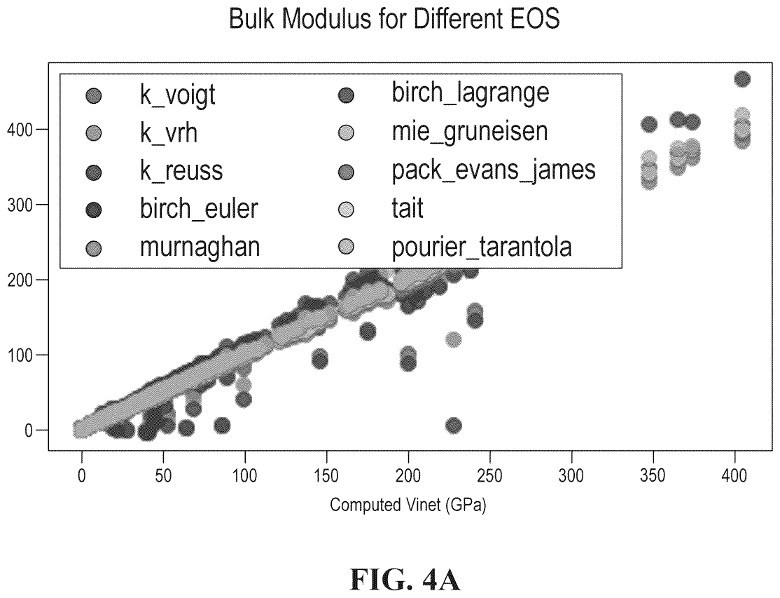

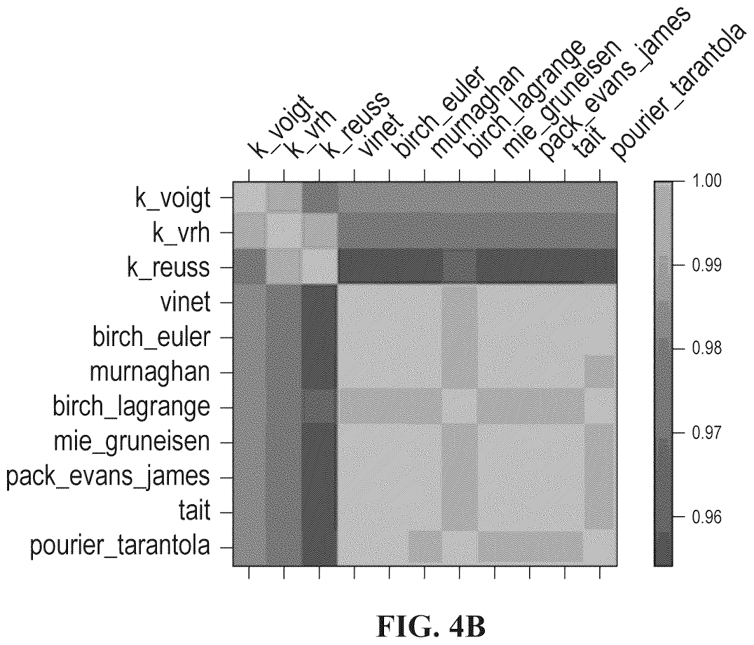

Regarding the bulk modulus, a computed Vinet equation of state was used for the EOS. The associated bulk modulus was fairly close to the other metrics, as shown in the FIGS. 4A and 4B. FIG. 4A shows a scatterplot of the bulk modulus, and FIG. 4B shows a correlation matrix.

It was revealed that very few materials have sufficiently low CTE to match AlN or GaN. The materials which are within the 5-15 ppm/K range (estimated values), have a Debye temperature of at most 1100 K, and a cost per kg up to $18/kg (10× the elemental cost of AlN) were identified.

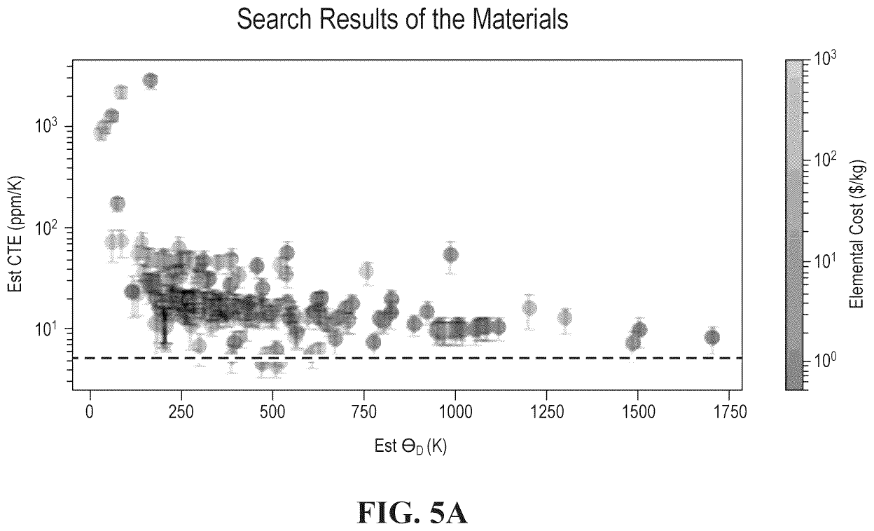

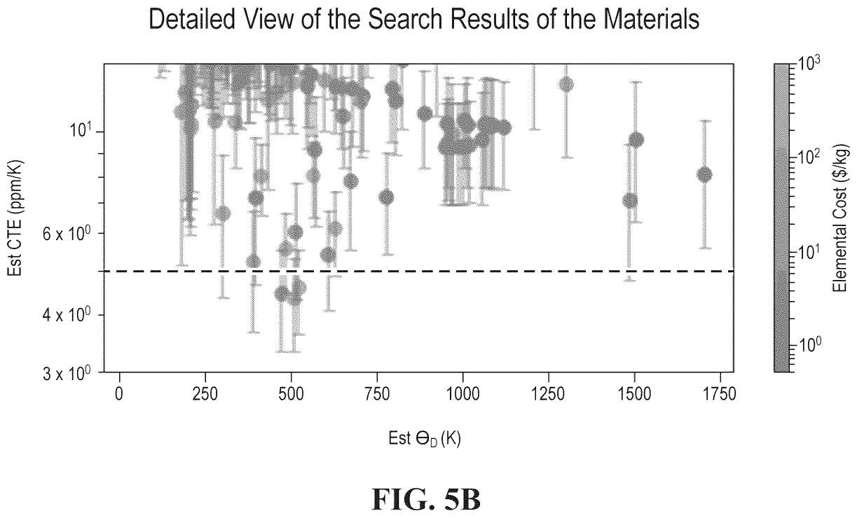

The search results are shown in FIGS. 5A and 5B and in Table 2. FIG. 5A shows the results of the materials database search with estimated CTE of the materials on the y axis, Debye temperature on the x axis, and cost shown by the depth of the color of the materials. The darker the color, the cheaper the material. FIG. 5B is a detailed view of a portion of FIG. 5A with the relevant materials identified. The reference material is bolded and Italicized in Table 2 below.

TABLE 2
Identified material candidates

| | | Bulk | Anharmonic | | | |
|---|---|---|---|---|---|---|
| Material | Cost per | modulus | bulk | Debye | | |
| Formula | kg | K | modulus K′ | temp. θ_{D} | CTE beta 1 | CTE beta 2 |
| TiO₂ | 10.048 | 227.789 | 4.359 | 1003.428 | 1.14E−05 | 6.95E−06 |
| CdCr₂O₄ | 2.785 | 165.002 | 4.524 | 710.042 | 1.46E−05 | 9.11E−06 |
| Cr₂O₃ | 2.782 | 207.536 | 4.469 | 890.324 | 1.34E−05 | 8.30E−06 |
| Al₂O₃ | 2.714 | 215.535 | 4.085 | 1089.352 | 1.30E−05 | 7.52E−06 |
| Al₂O₃ | 2.714 | 146.887 | 4.052 | 955.505 | 1.31E−05 | 7.55E−06 |
| AlN | 1.820 | 195.249 | 3.979 | 1057.434 | 1.22E−05 | 6.91E−06 |
| TiO₂ | 10.048 | 195.710 | 4.292 | 950.758 | 1.15E−05 | 6.90E−06 |
| ZnCr₂O₄ | 2.673 | 182.841 | 4.446 | 805.403 | 1.43E−05 | 8.83E−06 |
| VO₂ | 17.501 | 240.719 | 4.887 | 1005.952 | 1.27E−05 | 8.30E−06 |
| TiO₂ | 10.048 | 241.450 | 4.343 | 1020.701 | 1.15E−05 | 7.01E−06 |
| Ti | 14.760 | 112.617 | 3.639 | 568.823 | 1.19E−05 | 6.23E−06 |
| Al₂O₃ | 2.714 | 204.458 | 4.089 | 1069.208 | 1.31E−05 | 7.58E−06 |
| TiO₂ | 10.048 | 219.440 | 4.337 | 989.703 | 1.14E−05 | 6.95E−06 |
| Al₂O₃ | 2.714 | 175.217 | 4.081 | 1016.138 | 1.30E−05 | 7.53E−06 |
| TiO₂ | 10.048 | 205.996 | 4.325 | 968.946 | 1.14E−05 | 6.92E−06 |
| TiO₂ | 10.048 | 200.837 | 4.331 | 957.468 | 1.17E−05 | 7.08E−06 |
| Al₂O₃ | 2.714 | 209.655 | 4.092 | 1080.840 | 1.29E−05 | 7.48E−06 |
| Cr | 2.681 | 258.938 | 4.303 | 778.678 | 8.94E−06 | 5.40E−06 |
| Al₂O₃ | 2.714 | 200.398 | 4.100 | 1063.666 | 1.30E−05 | 7.55E−06 |

The materials in Table 2 were further evaluated based on additional known properties and behaviors associated with them. For example, TiO₂ and VO₂ have a known phase transition; TiO₂ at 500° C. and VO₂ at about 61.85° C., which is not desirable for a GaN substrate. Al₂O₃ has a high Debye temperature, and experimentally the CTE is known to change substantially above 526.85° C.

Therefore, the remaining materials emerged as good candidates for GaN interlayer materials: Cr₂O₃, ZnCr₂O₄, and CdCr₂O₄.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A gallium nitride (GaN) growth layer comprising:
a first surface;
a second surface; and
a bulk region extending between the first and second surfaces, the bulk region having a polycrystalline material with coefficient of thermal expansion (CTE) of about 2-25 ppm/K above 800 K and one or more spinel compounds having formula (I):
(ZnₓCd₁₋ₓ)(Cr_{y}Al_{1-y})₂O₄ (I),
where x and y are any number between 0 and 1,
one of the first and second surfaces including a GaN epitaxial growth region.

2. The layer of claim 1, wherein the first or second surface includes the polycrystalline material.

3. The layer of claim 1, wherein the polycrystalline material further comprises a compound of formula (II):
TiO_{2-δ} (II),
where δ is any number between 0 and 0.5, optionally including a fractional part.

4. The layer of claim 1, wherein the polycrystalline material is electrically conductive.

5. The layer of claim 1, wherein the first surface and the bulk region are encapsulated, the first surface including the GaN epitaxial growth region.

6. The layer of claim 1, wherein the first surface is a uniform surface and includes the GaN epitaxial growth region.

7. The layer of claim 1, wherein the polycrystalline material includes Cr₂O₃, ZnCr₂O₄, CdCr₂O₄, or their combinations.

8. A gallium nitrate (GaN) semiconductor wafer comprising:
a first layer including
a first surface having a GaN epitaxial growth region;
a second surface; and
a bulk region extending between the first and second surfaces, the bulk region having a polycrystalline material with coefficient of thermal expansion (CTE) of about 2-25 ppm/K above 800 K and one or more spinel compounds having formula (I):
(ZnₓCd₁₋ₓ)(Cr_{y}Al_{1-y})₂O₄ (I),
where x and y are any number between 0 and 1; and
a GaN epilayer adjacent the growth region.

9. The semiconductor wafer of claim 8, wherein the polycrystalline material further includes a compound of formula (II):
TiO_{2-δ} (II),
where δ is any number between 0 and 0.5, optionally including a fractional part.

10. The semiconductor wafer of claim 9, wherein the compound of formula (II) includes oxygen vacancies.

11. The semiconductor wafer of claim 8, wherein the polycrystalline material is electrically conductive.

12. The semiconductor wafer of claim 8, wherein the first layer and the bulk region are encapsulated.

13. The semiconductor wafer of claim 8, wherein the polycrystalline material includes Cr₂O₃, ZnCr₂O₄, CdCr₂O₄, or their combinations.

14. The semiconductor wafer of claim 8, wherein the polycrystalline material further includes carbon.

15. A gallium nitride (GaN) semiconductor device comprising:
a first layer including
a first surface having a GaN epitaxial growth region;
a second surface; and
a bulk region extending between the first and second surfaces, the bulk region having an electrically conductive, polycrystalline material with coefficient of thermal expansion (CTE) of about 2-25 ppm/K above 800 K and one or more spinel compounds having formula (I):
(ZnₓCd₁₋ₓ)(Cr_{y}Al_{1-y})₂O₄ (I)
where x and y are any number between 0 and 1; and
a GaN epilayer adjacent the growth region.

16. The device of claim 15, wherein the electrically conductive, polycrystalline material further includes an electrically conductive additive.

17. The device of claim 16, wherein the electrically conductive, polycrystalline material further comprises an oxygen vacancy-including compound having formula (II):
TiO_{2-δ} (II),
where δ is any number between 0 and 0.5 including a fractional part.

18. The device of claim 15, wherein the GaN epilayer is immediately adjacent the growth region.

19. The device of claim 15, wherein the device is a transistor.

20. The device of claim 15, wherein the conductive, polycrystalline material includes Cr₂O₃, ZnCr₂O₄, CdCr₂O₄, or their combinations.
